(19) United States
(12) Patent Application Publication
(10) Pub. No.: US 2024/0341134 A1
(43) Pub. Date: Oct. 10, 2024

(54) DISPLAY PANEL AND DISPLAY DEVICE

(71) Applicant: Wuhan China Star Optoelectronics Display Technology Co., Ltd., Wuhan (CN)

(72) Inventors: Zhongming CHEN, Wuhan (CN); Chunpeng ZHANG, Wuhan (CN); Hanchen LIU, Wuhan (CN); Wenxu XIANYU, Wuhan (CN)

(21) Appl. No.: 17/610,525

(22) PCT Filed: Sep. 18, 2021
(86) PCT No.: PCT/CN2021/119284

§ 371 Date: Apr. 30, 2024

(30) Foreign Application Priority Data
Sep. 10, 2021 (CN) 2021111061208.0

(51) Int. Cl. H10K 59/131

(52) U.S. Cl. CPC H10K 59/131

(57) ABSTRACT

A display panel and a display device are provided. The display panel includes a display area, a bonding area located adjacent to the display area, a substrate, and a first electrode, a common layer, and a second electrode laminated on the substrate. The display panel further includes a first metal layer disposed between the substrate and the common layer, and an undercut opening is defined in the first metal layer in the display area. The second electrode is connected to the first metal layer in the undercut opening.

### FIELD OF INVENTION

The present invention relates to a technical field of displays, and particularly to a display panel and a display device.

### BACKGROUND OF INVENTION

In prior art, organic light-emitting diodes (OLEDs) include anode layers, cathode layers, and organic functional layers located between the anode layers and the cathode layers. In actual production processes, the anode layers are fabricated by separate typesetting methods, the organic functional layers are formed on the anode layers by high-precision metal mask evaporation methods, and then the cathode layers are formed by full-surface evaporation methods.

Due to arrangement of the cathode layers on an entire surface and limitation of space and manufacturing processes, cathode signals can only be fed at two opposite sides of a display screen through constant low-level metal lines, for example, fed at a side close to an upper area and a side close to a lower area. As a result, frame widths of display panels near the constant low-level metal lines are too large, which are not conducive to narrowing frames of the display panels.

### SUMMARY OF INVENTION

### TECHNICAL PROBLEMS SUMMARY OF INVENTION

Embodiments of the present application provide a display panel and a display device to achieve a narrow bezel design of the display panel.

### SOLUTIONS TO PROBLEMS

### TECHNICAL SOLUTIONS

To achieve the above objects, an embodiment of the present application provides a display panel including a display area and a bonding area located adjacent to the display area.

The display panel includes a substrate, and a first electrode, a common layer, and a second electrode laminated on the substrate.

The display panel further includes a first metal layer disposed between the substrate and the common layer. An undercut opening is defined in the first metal layer in the display area. The second electrode is connected to the first metal layer in the undercut opening.

In the display panel provided by the embodiment, the second electrode comprises a first main portion disposed on the first metal layer and a first connecting portion connected to the first main portion, and wherein the first connecting portion is located in the undercut opening, at least part of the first connecting portion is disconnected from the first main portion at an inner wall of the undercut opening, and the first connecting portion is connected to the first metal layer at the inner wall.

In the display panel provided by the embodiment, the undercut opening passes through a side wall of the first metal layer, and the first connecting portion is connected to the first main portion from the side wall of the first metal layer.

In the display panel provided by the embodiment, the common layer comprises a second main portion and a second connecting portion, the second main portion is located between the first metal layer and the first main portion, the second connecting portion is located in the undercut opening, at least part of the second connecting portion is disconnected from the first main portion at the inner wall of the undercut opening, and the second connecting portion is located between the first connecting portion and the substrate.

In the display panel provided by the embodiment, the first metal layer comprises a first sub-metal layer and a second sub-metal layer arranged in a stacked arrangement on the substrate, the undercut opening comprises a first sub-undercut opening defined in the first sub-metal layer and a second sub-undercut opening defined in the second sub-metal layer, the first sub-undercut opening communicates with the second sub-undercut opening, and the second sub-undercut opening has a diameter greater than a diameter of the first sub-undercut opening.

In the display panel provided by the embodiment, the first metal layer comprises a first sub-metal layer, a second sub-metal layer, and a third sub-metal layer arranged in a stacked arrangement on the substrate, and the undercut opening comprises a first sub-undercut opening defined in the first sub-metal layer, a second sub-undercut opening defined in the second sub-metal layer, and a third sub-undercut opening defined in the third sub-metal layer, wherein the first sub-undercut opening, the second sub-undercut opening, and the third sub-undercut opening are in communication with each other, and wherein each of a diameter of the first sub-undercut opening and a diameter of the third sub-undercut opening is smaller than a diameter of the second sub-undercut opening.

In the display panel provided by the embodiment, the common layer comprises a second main portion and a second connecting portion, wherein the second main portion is located between the first metal layer and the first electrode, and the second connecting portion is located in the undercut opening, and wherein a thickness of the second connecting portion is less than a sum of depths of the third sub-undercut opening and the second sub-undercut opening.

In the display panel provided by the embodiment, the first sub-metal layer is made of titanium, the second sub-metal layer is made of aluminum, and the third sub-metal layer is made of titanium.

In the display panel provided by the embodiment, the display panel comprises a plurality of sub-pixels spaced apart from each other, and the first metal layer comprises a plurality of the undercut openings located in the display area, and a plurality of first metal traces extending from one end of the undercut openings to the bonding area.

The undercut openings and the first metal traces are all located in gaps between the sub-pixels.

In the display panel provided by the embodiment, the first metal layer further comprises a source/drain electrode layer located in the display area, and a plurality of second metal traces located in the bonding area, and wherein the second metal traces are connected to the first metal traces, respectively.

In the display panel provided by the embodiment, the undercut opening has a cross-section being Y-like, U-like, or C-like in shape in a direction parallel to the substrate.

The application further provides a display panel comprising a display area.

The display panel further comprises:
a substrate;
a first conductive layer disposed on the substrate;
an insulating layer disposed on the first conductive layer; and
a second conductive layer disposed on the insulating layer.

The first conductive layer comprises an opening defined in the display area, and the second conductive layer comprises a first main portion disposed on the first conductive layer and a first connecting portion connected to the first main portion, and wherein the first connecting portion is located in the opening, at least part of the first connecting portion is disconnected from the first main portion at an inner wall of the opening, and the first connecting portion is connected to the first conductive layer at the inner wall of the opening.

In the display panel provided by the embodiment, the opening passes through a side wall of the first conductive layer, and the first connecting portion is connected to the first main portion from the side wall of the first conductive layer.

In the display panel provided by the embodiment, the insulating layer includes a second main portion and a second connecting portion, the second main portion is located between the first conductive layer and the first main portion, the second connecting portion is located in the opening, at least part of the second connecting portion is disconnected from the first main portion at the inner wall of the opening, and the second connecting portion is located between the first connecting portion and the substrate.

In the display panel provided by the embodiment, the first conductive layer includes a second sub-conductive layer and a first sub-conductive layer disposed in a stacked arrangement on the substrate, the opening includes a first sub-opening defined in the first sub-conductive layer and a second sub-opening defined in the second sub-conductive layer, the first sub-opening communicates with the second sub-opening, and the second sub-opening has a diameter greater than a diameter of the first sub-opening.

In the display panel provided by the embodiment, a linear distance between at least part of the inner wall of the opening and a center line of the opening gradually increases in a direction from the first main portion to the first connecting portion.

The present application further provides a display device comprising a display panel comprising a display area and a bonding area located adjacent to the display area.

The display panel comprises a substrate, and a first electrode, a common layer, and a second electrode laminated on the substrate.

The display panel further comprises a first metal layer disposed between the substrate and the common layer, and an undercut opening is defined in the first metal layer in the display area, and wherein the second electrode is connected to the first metal layer in the undercut opening.

In the display device provided by the embodiment, the second electrode comprises a first main portion disposed on the first metal layer and a first connecting portion connected to the first main portion, and wherein the first connecting portion is located in the undercut opening, at least part of the first connecting portion is disconnected from the first main portion at an inner wall of the undercut opening, and the first connecting portion is connected to the first metal layer at the inner wall.

In the display device provided by the embodiment, the opening passes through a side wall of the first conductive layer, and the first connecting portion is connected to the first main portion from the side wall of the first conductive layer.

In the display device provided by the embodiment, the common layer comprises a second main portion and a second connecting portion, the second main portion is located between the first metal layer and the first main portion, the second connecting portion is located in the undercut opening, at least part of the second connecting portion is disconnected from the first main portion at the inner wall of the undercut opening, and the second connecting portion is located between the first connecting portion and the substrate.

### BENEFICIAL EFFECTS OF INVENTION

### BENEFICIAL EFFECTS

The present application has advantageous effects as follows: the embodiments of the present application provide the display panel and the display device. The display panel includes the display area and the bonding area located adjected to the display area, and also includes the substrate, and the first electrode, the common layer, and the second electrode all laminated on the substrate. In detail, the display panel further includes the first metal layer disposed between the substrate and the common layer. By forming the undercut opening in the first metal layer in the display area, the second electrode is connected to the first metal layer in the undercut opening, so that electrical signals received by the second electrode are no longer transmitted through metal traces surrounding the display area in the prior art but transmitted through the first metal layer located in the display area of the present application, thereby achieving a narrow bezel design of the display panel.

### BRIEF DESCRIPTION OF DRAWINGS

### DESCRIPTION OF DRAWINGS

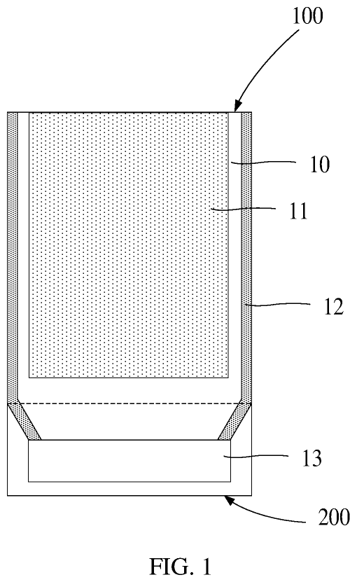

FIG. 1 is a top plan view of a display panel in prior art.

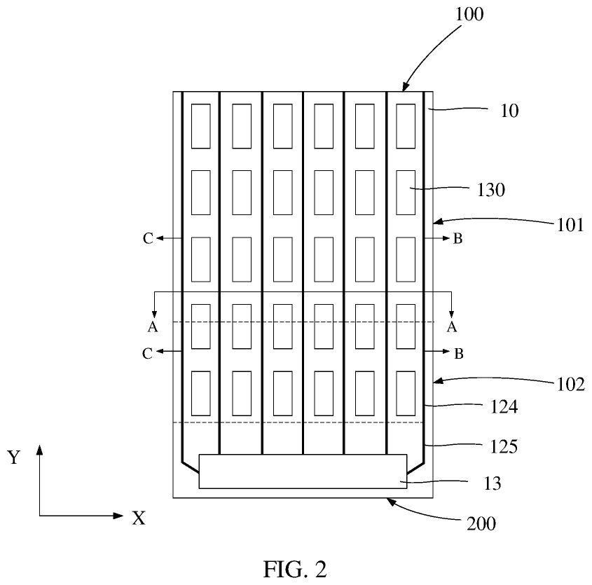

FIG. 2 is a top plan view of a display panel provided by an embodiment of the present application.

FIG. 3 is a first cross-sectional view taken along line A-A of FIG. 2.

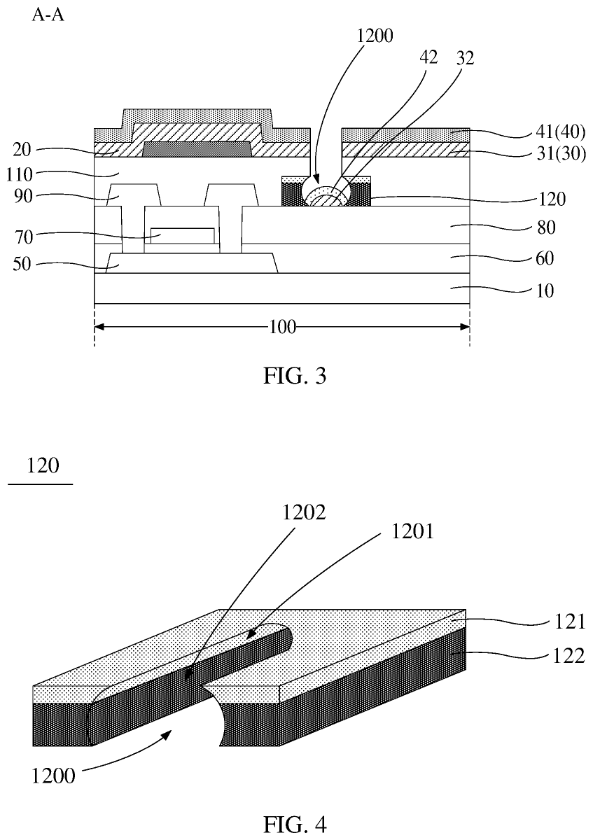

FIG. 4 is a first schematic structural view of a first meal layer provided by an embodiment of the present application.

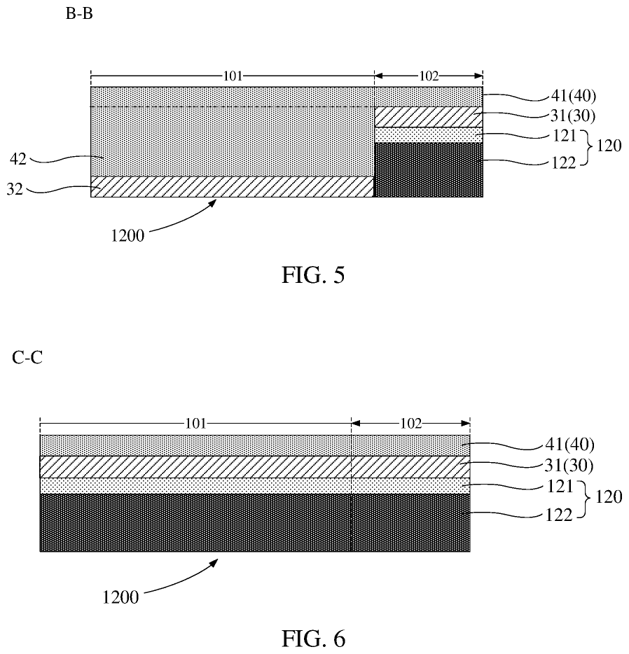

FIG. 5 is a first cross-sectional view taken along line B-B of FIG. 2.

FIG. 6 is a cross-sectional view taken along line C-C of FIG.

2.

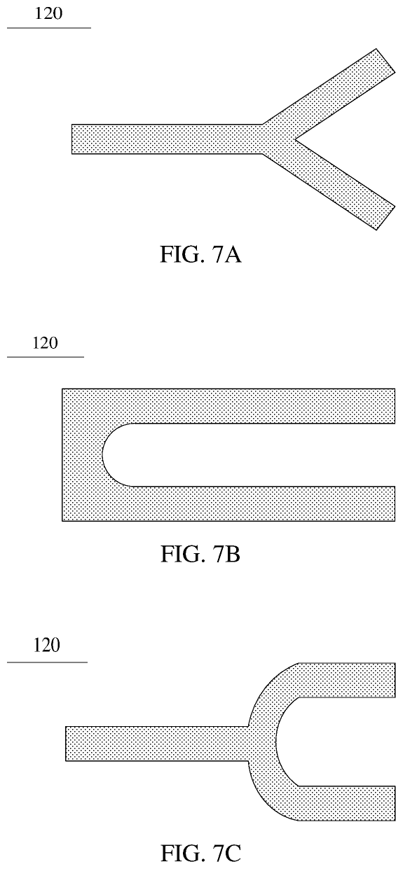

FIGS. 7A to 7C are top plan views of the first meal layer provided by embodiments of the present application.

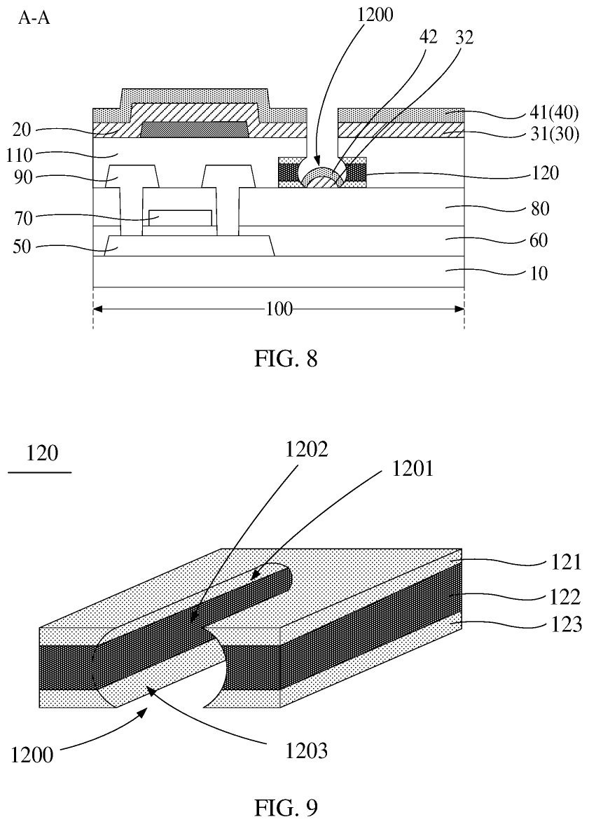

FIG. 8 is a second cross-sectional view taken along line A-A of FIG. 2.

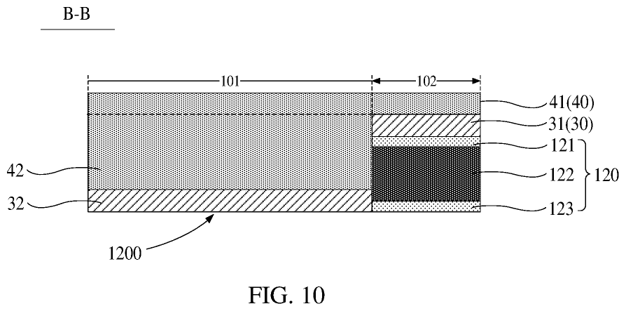

FIG. 9 is a second schematic structural view of the first meal layer provided by an embodiment of the present application.

FIG. 10 is a second cross-sectional view taken along line B-B of FIG. 2.

### EMBODIMENTS OF INVENTION

### EMBODIMENTS OF INVENTION

The present application provides a display panel and a display device. In order to make the objectives, technical solutions, and effects of the present application clearer, the present application will be further described in detail below with reference to the accompanying drawings and embodiments. It should be understood that the specific embodiments described here are only used to illustrate the present application, and are not used to limit the present application.

Embodiments of the present application provide a display panel and a display device. Detailed descriptions are given below. It should be noted that the description order of the following embodiments is not intended to limit the preferred order of the embodiments.

Please refer to FIG. 1, which is a top plan view of a display panel in prior art.

In the prior art, a display panel includes a display area 100 and a bonding area 200 located adjacent to the display area 100. The display panel includes an anode layer (not shown) stacked on a substrate 10, a cathode layer 11, and a common layer (not shown) located between the anode layer and the cathode layer 11. The display panel further includes a chip-on-film 13 located in the bonding area. The chip-on-film 13 transmits a cathode signal to the cathode layer 11 through a constant low-level metal line (VSS) 12. In detail, in actual production processes, the anode layer is fabricated by a separate typesetting method, the common layer is formed on the anode layer by high-precision metal mask evaporation method, and then the cathode layer 11 is formed by full-surface evaporation method.

Due to arrangement of the cathode layer 11 on an entire surface and limitation of space and manufacturing processes, the cathode signal can only be fed at two opposite sides of a display screen through a constant low-level metal line 12, for example, fed at a side close to an upper area and a side close to a lower area. As a result, a frame width of the display panel near the constant low-level metal line 12 is too large, which is not conducive to narrowing a frame of the display panel. Therefore, the embodiments of the present application provide a display panel and a display device to improve the above-mentioned defects.

Referring to FIG. 2 to FIG. 7C, the present application provides a display panel and a display device. The display panel includes a display area 100. The display panel includes a substrate 10, and a first electrode 20, a common layer 30, and a second electrode 40 all laminated on the substrate 10. Specifically, the display panel further includes a first metal layer 120 disposed between the substrate 10 and the common layer 30, and the first metal layer 120 is provided with an undercut opening 1200 formed in the display area 100. Specifically, the second electrode 40 is connected to the first metal layer 120 in the undercut opening 1200. By forming the undercut opening 1200 in the first metal layer 120 in the display area 100, and making the second electrode 40 be connected to the first metal layer 120 in the undercut opening 1200, the present application fulfills a narrow bezel design of the display panel.

The technical solution of the present application will now be described in combination with specific embodiments.

### Embodiment 1

Please refer to FIGS. 2 and 3, FIG. 2 is a top plan view of the display panel provided by an embodiment of the present application.

This embodiment provides a display panel including a display area 100 and a bonding area 200 located adjacent to the display area 100.

It should be noted that the display panel includes, but is not limited to, organic light-emitting diode (OLED). Further, in this embodiment, the technical solution of this embodiment is described by taking the display panel as an OLED as an example.

In this embodiment, the substrate 10 may include a rigid substrate or a flexible substrate. When being the rigid substrate, a material of the substrate 10 can be metal or glass. When being the flexible substrate, a material of the substrate 10 may include at least one of acrylic resin, methacrylic resin, polyisoprene, vinyl resin, epoxy-based resin, polyurethane-based resin, cellulose resin, silicone resin, polyimide-based resin, or polyamide-based resin. The material of the substrate 10 is not limited in this embodiment.

In this embodiment, the first electrode 20 includes, but is not limited to, an anode, and the second electrode 40 includes, but is not limited to, a cathode. The common layer 30 includes, but is not limited to, a hole injection layer, a hole transport layer, a light emitting layer, an electron buffer layer, and an electron transport layer, which are not specifically limited in this embodiment.

In detail, the display panel includes an active layer 50, a first insulating layer 60, a gate electrode 70, a second insulating layer 80, a source/drain electrode 90, and a third insulating layer 110 disposed between the substrate 10 and the first electrode 20. The display panel further includes a first metal layer 120 disposed between the substrate 10 and the common layer 30.

It can be understood that the active layer 50, the first insulating layer 60, the gate electrode 70, the second insulating layer 80, the source and drain electrode 90, and the third insulating layer 110 all disposed between the substrate 10 and the first electrode 20 and included in the display panel are only used as an example for illustration, and this embodiment does not limit film structures of the display panel.

Please refer to FIG. 4, which is a first schematic structural view of a first meal layer provided by an embodiment of the present application.

In this embodiment, the first metal layer 120 is provided with an undercut opening 1200 located in the display area 100. A linear distance between at least part of an inner wall of the undercut opening 1200 and a center line of the undercut opening gradually increases in a direction from the first main portion to the first connecting portion, so that a film formed in the undercut opening is forced to break at the inner wall.

Further, in this embodiment, the first metal layer 120 includes a first sub-metal layer 121 and a second sub-metal layer 122 disposed in a stacked arrangement on the substrate 10. The undercut opening 1200 includes a first sub-undercut opening 1201 located in the first sub-metal layer 121 and a second sub-undercut opening 1202 located in the second sub-metal layer 122. The first sub-undercut opening 1201 communicates with the second sub-undercut opening 1202, a diameter of the second sub-undercut opening 1202 is greater than a diameter of the first sub-undercut opening 1201, so that a cross-sectional area of the undercut opening 1200 gradually reduces in a direction perpendicular to the substrate 10, thereby forcing the film formed in the undercut opening 1200 to break at the inner wall.

It should be noted that the diameter of the first sub-undercut opening 1201 and the diameter of the second sub-undercut opening 1202 are both related to actual manufacturing processes, which are not specifically limited in this embodiment.

In this embodiment, a material of the first sub-metal layer 121 includes, but is not limited to, titanium and molybdenum, and a material of the second sub-metal layer 122 includes but is not limited to aluminum. This embodiment takes the material of the first sub-metal layer 121 as titanium and the material of the second sub-metal layer 122 as aluminum as an example for description.

It should be noted that in this embodiment, the undercut opening 1200 is formed by etching away the first sub-metal layer 121 and the second sub-metal layer 122 through a wet etching method. Specifically, since the material of the first sub-metal layer 121 and the material of the second sub-metal layer 122 are different from each other, when both are subjected to wet etching at a same time, an etching rate of the first sub-metal layer 121 and an etching rate of the second sub-metal layer 122 may be quite different from each other. Specifically, the etching rate of the second sub-metal layer 122 is greater than the etching rate of the first sub-metal layer 121, thereby forming the first sub-undercut opening 1201 and the second sub-undercut opening 1202 with different opening diameters. Further, the third insulating layer 110 is provided with an opening (not labeled), and the opening at least exposes the undercut opening 1200.

It is understood that in this embodiment, the wet etching method used to form the undercut opening 1200 by etching away the first sub-metal layer 121 and the second sub-metal layer 122 is only taken as an example for illustration, and this embodiment does not specifically limit a preparation method of the undercut opening 1200

Referring to FIGS. 2, 3, 5, and 6, FIG. 5 is a first cross-sectional view taken along line B-B of FIG. 2, and FIG. 6 is a cross-sectional view taken along line C-C of FIG. 2.

In this embodiment, the second electrode 40 includes a first main portion 41 disposed on the first metal layer 120 and a first connecting portion 42 connected to the first main portion 41, wherein the first connecting portion 42 is located in the undercut opening 1200, at least part of the first connecting portion 42 is disconnected from the first main portion 41 at the inner wall of the undercut opening 1200, and the first connecting portion 42 is connected to the first metal layer 120 at the inner wall, thereby enabling the second electrode 40 to be connected to the first metal layer 120 in the undercut opening 1200.

Specifically, the undercut opening 1200 passes through a side wall of the first metal layer 120, and the first connecting portion 42 is connected to the first main portion 41 from the side wall. It can be understood that the side wall of the first metal layer 120 includes a first side wall (not labeled), a second side wall (not labeled), and a third side wall (not labeled). The first side wall, the second side wall, and the third side wall are smoothly adjoined, and the third side wall is located between the first side wall and the second side wall. In this embodiment, a location of a juncture of the first connecting portion 42 and the first main portion 41 is not specifically limited. That is, the first connecting portion 42 is connected to the first main portion 41 at the first side wall, or the first connecting portion 42 is connected to the first main portion at the second side wall, or the first connecting portion 42 is connected to the first main portion 41 at the third side wall.

In this embodiment, the common layer 30 includes a second main portion 31 and a second connecting portion 32. The second main portion 31 is disposed between the first metal layer 120 and the first main portion 41, the second connecting portion 32 is located in the undercut opening 1200, at least part of the second connecting portion 32 is disconnected from the first main portion 41 at the inner wall of the undercut opening 1200, and the second connecting portion 32 is disposed between the first connecting portion 42 and the substrate 10, so that the second connecting portion 32 serves to support the first connecting portion 42. A contact area between the first connecting portion 42 and the sidewall of the first metal layer 120 can be increased by thickening the first connecting portion 42, thereby improving a connection effect between the second electrode 40 and the first metal layer 120. It should be noted that in this embodiment, a thickness of the second connecting portion 32 is less than a depth of the second sub-undercut opening 1202, so as to prevent the contact area between the first connecting portion 42 and the sidewall of the first metal layer 120 from being too small, thereby adversely affecting the connection effect between the second electrode 40 and the first metal layer 120.

Further, in this embodiment, the display panel includes a plurality of sub-pixels 130 spaced apart from each other, the first metal layer 120 includes a plurality of the undercut openings 1200 located in the display area 100, and a plurality of first metal traces 124 extending from one end of the undercut openings 1200 to the bonding area 200. Specifically, the undercut openings 1200 and the first metal traces 124 are all located in gaps between the sub-pixels 130, so as not to affect each of the sub-pixels 130 in the display area 100 to display normally.

It can be understood that in this embodiment, each of the first metal traces 124 may extend in a first direction or a second direction, or may pass through the gap between two adjacent rows of the sub-pixels 130, or may only extend to a middle position of the display panel, which is not specifically limited in this embodiment. Also, each of the first metal traces 124 may be a straight line or a broken line, and a shape of the first metal trace 124 is not specifically limited in this embodiment, wherein the first direction is an X direction, the second direction is a Y direction, and the first direction is perpendicular to the second direction.

It should be noted that in this embodiment, the display area 100 includes a first display area 101 and a second display area 102 located between the first display area 101 and the bonding area 200. The undercut opening 1200 is located in the first display area 101, or extends from the second display area 102 to the first display area 101. A length of the undercut opening 1200 in this embodiment is not limited. Further, in this embodiment, the undercut opening 1200 is located in the first display area 101 as an example for illustration.

In this embodiment, the display panel further includes a chip-on-film 13 located in the bonding area 200. The first metal layer 120 further includes a plurality of second metal traces 125 disposed in the bonding area 200. The second metal traces 125 are connected to the first metal traces 124, respectively, and the chip-on-film 13 transmits electrical signals to the first metal traces 124 through the second metal traces 125. In this embodiment, the second metal traces 125 include, but is not limited to, constant low-level metal lines (VSS). One end of each of the second metal traces 125 is connected to corresponding one of the first metal traces 124, and the other end of each of the second metal traces 125 is connected to the chip-on-film 13, so that the electrical signals are transmitted to the second electrode 40 through the first metal trace 124.

It can be understood that in this embodiment, the first metal traces 124, the second metal traces 125, and the source/drain electrode 90 are arranged in a same layer and may be manufactured in a same process, so that influence on thickness of the display panel can be minimized.

The embodiment provides the display panel including the display area 100 and the bonding area 200 located adjacent to the display area 100. The display panel includes the substrate 10, and the first electrode 20, the common layer 30, and the second electrode 40 all laminated on the substrate 10. Specifically, the first electrode 20 is an anode, the common layer 30 including the hole injection layer, the hole transport layer, the light-emitting layer, the electron buffer layer, and the electron transport layer that are laminated on the first electrode 20, and the second electrode 40 is a cathode. The display panel further includes the first metal layer 120 disposed between the substrate 10 and the common layer 30. The first metal layer 120 includes the undercut openings 1200 located in the display area 100, the first metal traces 124, and the second metal traces 125 located in the bonding area 200. Specifically, the second electrode 40 is connected to the first metal layer 120 in the undercut openings 1200, and the second metal traces 125 are constant low-level metal lines.

In this embodiment, the second electrode 40 is connected to the first metal layer 120 in the undercut openings 1200, and the first metal layer 120 is connected to the first metal traces 124 extending from one end of the undercut openings 1200 to the bonding area 200, and the second metal traces 125 located in the bonding area 200, so that cathode signals can be transmitted to the second electrode 40 through the first metal traces 124. In this manner, electrical signals introduced through metal traces surrounding the display area 100 in the prior art are introduced through the first metal layer 120 located in the display area 100 of the present application, thereby achieving a narrow bezel design of the display panel.

It should be noted that for further details please refer to FIGS. 7A to 7C, which are top plan views of the first meal layer 120 provided by the embodiments of the present application. Each of the undercut openings has a cross-section being Y-like, U-like, or C-like in shape in a direction parallel to the substrate 10, which is not specifically limited in this embodiment. It can be understood that in this embodiment, by forming the undercut opening 1200 as a semi-closed structure, the first connecting portion 42 of the second electrode 40 can be limited in an enclosed area formed by the undercut opening 1200, so as to ensure the connection effect of the second electrode 40 and the first metal layer 120.

### Embodiment 2

Please refer to FIGS. 2, 8, 9, and 10. FIG. 8 is a second cross-sectional view taken along line A-A of FIG. 2. FIG. 9 is a second schematic structural view of the first meal layer 120 provided by the embodiment of the present application. FIG. 10 is a second cross-sectional view taken along line B-B of FIG. 2.

In this embodiment, a structure of the display panel is similar/same as the first type structure of the display panel provided in the above embodiment. For details, please refer to the description of the display panel in the above embodiment, which will not be repeated here. This embodiment differs from the above-mentioned embodiment in that:

In this embodiment, the first metal layer 120 is provided with an undercut opening 1200 located in the display area 100. A linear distance between at least part of an inner wall of the undercut opening 1200 and a center line of the undercut opening is varied such that the linear distance gradually increases first and then decreases, so that a film formed in the undercut opening is forced to break at the inner wall.

Further, in this embodiment, the first metal layer 120 includes a third sub-metal layer 123, a second sub-metal layer 122, and a first sub-metal layer 121 disposed in a stacked arrangement on the substrate 10. The undercut opening 1200 includes a first sub-undercut opening 1201 located in the first sub-metal layer 121, a second sub-undercut opening 1202 located in the second sub-metal layer 122, and a third sub-undercut opening 1203 located in the third sub-metal layer 123. The first sub-undercut opening 1201, the second sub-undercut opening 1202, and the third sub-undercut opening 1203 communicate with each other. Each of a diameter of the first sub-undercut opening 1201 and a diameter of the third sub-undercut opening 1203 is less than a diameter of the second sub-undercut opening 1202, so that a cross-sectional area of the undercut opening 1200 gradually increases first and then decreases in a direction perpendicular to the substrate 10, thereby forcing a film formed in the undercut opening to break at the inner wall.

It should be noted that the diameter of the first sub-undercut opening 1201, the diameter of the second sub-undercut opening 1202, and the diameter of the third sub-undercut opening 1203 are all related to actual manufacturing processes, which are not specifically limited in this embodiment.

In this embodiment, a material of the first sub-metal layer 121 includes, but is not limited to, titanium and molybdenum, a material of the second sub-metal layer 122 includes but is not limited to aluminum, and a material of the third sub-metal layer 123 includes, but is not limited to, titanium and molybdenum. This embodiment takes the material of the first sub-metal layer 121 as titanium, the material of the second sub-metal layer 122 as aluminum, and the material of the third sub-metal layer 123 as titanium as an example for description.

It should be noted that in this embodiment, the undercut opening 1200 is formed by etching away the first sub-metal layer 121, the second sub-metal layer 122, and the third sub-metal layer 123 through a wet etching method. Specifically, since the material of the first sub-metal layer 121 and the material of the second sub-metal layer 122 are different, the material of the first sub-metal layer 121 and the material of the third sub-metal layer 123 are the same. Therefore, when the three sub-metal layers are subjected to wet etching at a same time, an etching rate of the first sub-metal layer 121 and an etching rate of the third sub-metal layer 122 are same, and the etching rate of the first sub-metal layer 121 and an etching rate of the second sub-metal layer 122 may be quite different from each other. Specifically, the etching rate of the second sub-metal layer 122 is greater than the etching rate of the first sub-metal layer 121, and the etching rate of the second sub-metal layer 122 is greater than the etching rate of the third sub-metal layer 123, thereby forming the first sub-undercut opening 1201, the second sub-undercut opening 1202, and third sub-undercut opening 1203 with different opening diameters. Further, the third insulating layer 110 is provided with an opening (not labeled), and the opening at least exposes the undercut opening 1200.

It is understood that in this embodiment, the wet etching method used to form the undercut opening 1200 by etching away the first sub-metal layer 121, the second sub-metal layer 122, and third sub-metal layer 123 is only taken as an example for illustration, and this embodiment does not specifically limit a preparation method of the undercut opening 1200.

In this embodiment, the second electrode 40 includes a first main portion 41 disposed on the first metal layer 120 and a first connecting portion 42 connected to the first main portion 41, wherein the first connecting portion 42 is located in the undercut opening 1200, at least part of the first connecting portion 42 is disconnected from the first main portion 41 at the inner wall of the undercut opening 1200, and the first connecting portion 42 is connected to the first metal layer 120 at the inner wall, thereby enabling the second electrode 40 to be connected to the first metal layer 120 in the undercut opening 1200.

Specifically, the undercut opening 1200 passes through a side wall of the first metal layer 120, and the first connecting portion 42 is connected to the first main portion 41 from the side wall. It can be understood that the side wall of the first metal layer 120 includes a first side wall (not labeled), a second side wall (not labeled), and a third side wall (not labeled). The first side wall, the second side wall, and the third side wall are smoothly adjoined, and the third side wall is located between the first side wall and the second side wall. In this embodiment, a location of a juncture of the first connecting portion 42 and the first main portion 41 is not specifically limited. That is, the first connecting portion 42 is connected to the first main portion 41 at the first side wall, or the first connecting portion 42 is connected to the first main portion at the second side wall, or the first connecting portion 42 is connected to the first main portion 41 at the third side wall.

In this embodiment, the common layer 30 includes a second main portion 31 and a second connecting portion 32. The second main portion 31 is disposed between the first metal layer 120 and the first main portion 41, the second connecting portion 32 is located in the undercut opening 1200, at least part of the second connecting portion 32 is disconnected from the first main portion 41 at the inner wall of the undercut opening 1200, and the second connecting portion 32 is disposed between the first connecting portion 42 and the substrate 10, so that the second connecting portion 32 serves to support the first connecting portion 42. A contact area between the first connecting portion 42 and the sidewall of the first metal layer 120 can be increased by thickening the first connecting portion 42, thereby improving a connection effect between the second electrode 40 and the first metal layer 120. It should be noted that in this embodiment, a thickness of the second connecting portion 32 is less than a sum of depths of diameters. the third sub-undercut opening 1203 and the second sub-undercut opening 1202, so as to prevent the contact area between the first connecting portion 42 and the sidewall of the first metal layer 120 from being too small, thereby adversely affecting the connection effect between the second electrode 40 and the first metal layer 120.

### Embodiment 3

An embodiment of the present application further provides a display panel including a display area. The display panel includes a substrate; a first conductive layer is disposed on the substrate; an insulating layer is disposed on the first conductive layer; and a second conductive layer is disposed on the insulating layer. The first conductive layer includes an opening defined in the display area, and the second conductive layer includes a first main portion disposed on the first conductive layer and a first connecting portion connected to the first main portion, and wherein the first connecting portion is located in the opening, at least part of the first connecting portion is disconnected from the first main portion at an inner wall of the opening, and the first connecting portion is connected to the first conductive layer at the inner wall of the opening.

It should be noted that in this embodiment, types of the first conductive layer, the insulating layer, and the second conductive layer are not specifically limited.

In this embodiment, the display panel further includes a bonding area located adjacent to the display area, and the display panel includes a chip-on-film located in the bonding area. The first conductive layer includes a plurality of the openings in the display area, a plurality of first metal traces extending from one end of the openings to the bonding area, and a plurality of second metal traces located in the bonding area. The second metal traces are connected to the first metal traces, respectively. The chip-on-film transmits electrical signals to the first metal traces through the second metal traces.

In this embodiment, the opening passes through a side wall of the first conductive layer, and the first connecting portion is connected to the first main portion from the side wall of the first conductive layer.

In this embodiment, the insulating layer includes a second main portion and a second connecting portion, the second main portion is located between the first conductive layer and the first main portion, the second connecting portion is located in the opening, at least part of the second connecting portion is disconnected from the first main portion at the inner wall of the opening, and the second connecting portion is located between the first connecting portion and the substrate.

In this embodiment, the first conductive layer includes a second sub-conductive layer and a first sub-conductive layer disposed in a stacked arrangement on the substrate, the opening includes a first sub-opening defined in the first sub-conductive layer and a second sub-opening defined in the second sub-conductive layer, the first sub-opening communicates with the second sub-opening, and the second sub-opening has a diameter greater than a diameter of the first sub-opening.

In this embodiment, a linear distance between at least part of the inner wall of the opening and a center line of the opening gradually increases in a direction from the first main portion to the first connecting portion, so that a film formed in the undercut opening is forced to break at the inner wall.

It should be noted that in another embodiment, the first conductive layer includes a third sub-conductive layer, a second sub-conductive layer, and a first sub-conductive layer laminated on the substrate. The opening includes a first sub-opening defined in the first sub-conductive layer, a second sub-opening defined in the second sub-conductive layer, and a third sub-opening defined in the third sub-conductive layer. The first sub-opening, the second sub-opening, and the third sub-opening communicate with each other. Each of a diameter of the first sub-opening and a diameter of the third sub-opening is less than a diameter of the second sub-opening, so that a cross-sectional area of the opening gradually increases first and then decreases in a direction perpendicular to the substrate, thereby forcing a film formed in the opening to break at the inner wall.

In this embodiment, by providing the first conductive layer including the openings in the display area, the first metal traces extending from one end of the openings to the bonding area, and the second metal traces located in the bonding area, the second metal traces are connected to the first metal traces, respectively, and the chip-on-film transmits electrical signals to the first metal traces through the second metal traces, thereby enabling electrical signals introduced through metal traces surrounding the display area in the prior art to be introduced through the first metal layer located in the display area of the present application, thereby achieving a narrow bezel design of the display panel.

### Embodiment 4

An embodiment of the present application further provides a display device, including the display panel as described in any of the above-mentioned embodiments, and a terminal body. The terminal body and the display panel are combined into one piece.

Specifically, for a specific structure of the display panel, please refer to the embodiment of the display panel of any of the above-mentioned embodiments, and the details of the embodiment of the present application will not be repeated here.

In this embodiment, the terminal body may include a middle frame, sealant, etc., which is not specifically limited here.

In actual applications, the display device may be a smart phone, a tablet computer, a notebook computer, a smart bracelet, a smart watch, smart glasses, a smart helmet, a desktop computer, a smart television, or a digital camera.

Accordingly, the present application provides a display panel and a display device. The display panel includes a display area and a bonding area located adjacent to the display area, and also includes a substrate, and a first electrode, a common layer, and a second electrode all laminated on the substrate. Specifically, the display panel further includes a first metal layer disposed between the substrate and the common layer, and the first metal layer is provided with an undercut opening formed in the display area. Specifically, the second electrode is connected to the first metal layer in the undercut opening. In the present application, by forming the undercut opening in the first metal layer in the display area, the second electrode is connected to the first metal layer in the undercut opening, so that electrical signals received by the second electrode are no longer transmitted through metal traces surrounding the display area in the prior art but transmitted through the first metal layer located in the display area of the present application, thereby achieving a narrow bezel design of the display panel.

It can be understood that for those of ordinary skill in the art, equivalent substitutions or changes can be made according to the technical solution and inventive concept of the present application, and all these changes or substitutions should fall within the protection scope of the appended claims of the present application.

What is claimed is:

1. A display panel comprising a display area and a bonding area located adjacent to the display area;
wherein the display panel further comprises a substrate and a first electrode, a common layer, and a second electrode laminated on the substrate; and
wherein the display panel further comprises a first metal layer disposed between the substrate and the common layer, and an undercut opening is defined in the first metal layer in the display area, and wherein the second electrode is connected to the first metal layer in the undercut opening.

2. The display panel of claim 1, wherein the second electrode comprises a first main portion disposed on the first metal layer and a first connecting portion connected to the first body portion, and wherein the first connecting portion is located in the undercut opening, at least part of the first connecting portion is disconnected from the first main portion at an inner wall of the undercut opening, and the first connecting portion is connected to the first metal layer at the inner wall.

3. The display panel of claim 2, wherein the undercut opening passes through a side wall of the first metal layer, and the first connecting portion is connected to the first main portion from the side wall of the first metal layer.

4. The display panel of claim 2, wherein the common layer comprises a second main portion and a second connecting portion, the second main portion is located between the first metal layer and the first main portion, the second connecting portion is located in the undercut opening, at least part of the second connecting portion is disconnected from the first main portion at the inner wall of the undercut opening, and the second connecting portion is located between the first connecting portion and the substrate.

5. The display panel of claim 1, wherein the first metal layer comprises a first sub-metal layer and a second sub-metal layer arranged in a stacked arrangement on the substrate, the undercut opening comprises a first sub-undercut opening defined in the first sub-metal layer and a second sub-undercut opening defined in the second sub-metal layer, the first sub-undercut opening communicates with the second sub-undercut opening, and the second sub-undercut opening has a diameter greater than a diameter of the first sub-undercut opening.

6. The display panel of claim 1, wherein the first metal layer comprises a first sub-metal layer, a second sub-metal layer, and a third sub-metal layer arranged in a stacked arrangement on the substrate, and the undercut opening comprises a first sub-undercut opening defined in the first sub-metal layer, a second sub-undercut opening defined in the second sub-metal layer, and a third sub-undercut opening defined in the third sub-metal layer, wherein the first sub-undercut opening, the second sub-undercut opening, and the third sub-undercut opening are in communication with each other, and wherein each of a diameter of the first sub-undercut opening and a diameter of the third sub-undercut opening is smaller than a diameter of the second sub-undercut opening.

7. The display panel of claim 6, wherein the common layer comprises a second main portion and a second connecting portion, wherein the second main portion is located between the first metal layer and the first electrode, and the second connecting portion is located in the undercut opening, and wherein a thickness of the second connecting portion is less than a sum of depths of the third sub-undercut opening and the second sub-undercut opening.

8. The display panel of claim 7, wherein the first sub-metal layer is made of titanium, the second sub-metal layer is made of aluminum, and the third sub-metal layer is made of titanium.

9. The display panel of claim 1, wherein the display panel comprises a plurality of sub-pixels spaced apart from each other, and the first metal layer comprises a plurality of the undercut openings located in the display area and a plurality of first metal traces extending from one end of the undercut openings to the bonding area; and
wherein the undercut openings and the first metal traces are all located in gaps between the sub-pixels.

10. The display panel of claim 9, wherein the first metal layer further comprises a source/drain electrode layer located in the display area and a plurality of second metal traces located in the bonding area, and wherein the second metal traces are connected to the first metal traces, respectively.

11. The display panel of claim 1, wherein the undercut opening has a cross-section being Y-like, U-like, or C-like in shape in a direction parallel to the substrate.

12. A display panel comprising a display area and a bonding area located adjacent to the display area;
wherein the display panel further comprises:
a substrate;
a first conductive layer disposed on the substrate;
an insulating layer disposed on the first conductive layer; and
a second conductive layer disposed on the insulating layer; and
wherein the first conductive layer comprises an opening defined in the display area, and the second conductive layer comprises a first main portion disposed on the first conductive layer and a first connecting portion connected to the first main portion, and wherein the first connecting portion is located in the opening, at least part of the first connecting portion is disconnected from the first main portion at an inner wall of the opening, and the first connecting portion is connected to the first conductive layer at the inner wall.

13. The display panel of claim 12, wherein the opening passes through a side wall of the first conductive layer, and the first connecting portion is connected to the first main portion from the side wall.

14. The display panel of claim 12, wherein the insulating layer comprises a second main portion and a second connecting portion, the second main portion is located between the first conductive layer and the first main portion, the second connecting portion is located in the opening, at least part of the second connecting portion is disconnected from the first main portion at the inner wall of the opening, and the second connecting portion is located between the first connecting portion and the substrate.

15. The display panel of claim 12, wherein the first conductive layer comprises a first sub-conductive layer and a second sub-conductive layer arranged in a stacked arrangement on the substrate, the opening comprises a first sub-opening defined in the first sub-conductive layer and a second sub-opening defined in the second sub-conductive layer, the first sub-opening communicates with the second sub-opening, and the second sub-opening has a diameter greater than a diameter of the first sub-opening.

16. The display panel of claim 15, wherein a linear distance between at least part of the inner wall of the opening and a center line of the opening gradually increases in a direction from the first main portion to the first connecting portion.

17. A display device, comprising a display panel comprising a display area and a bonding area located adjacent to the display area;
wherein the display panel further comprises a substrate and a first electrode, a common layer, and a second electrode laminated on the substrate; and
wherein the display panel further comprises a first metal layer disposed between the substrate and the common layer, and an undercut opening is defined in the first metal layer in the display area, and wherein the second electrode is connected to the first metal layer in the undercut opening.

18. The display device of claim 17, wherein the second electrode comprises a first main portion disposed on the first metal layer and a first connecting portion connected to the first body portion, wherein the first connecting portion is located in the undercut opening, at least part of the first connecting portion is disconnected from the first main portion at an inner wall of the undercut opening, and the first connecting portion is connected to the first metal layer at the inner wall.

19. The display device of claim 18, wherein the undercut opening passes through a side wall of the first metal layer, and the first connecting portion is connected to the first main portion from the side wall of the first metal layer.

20. The display device of claim 18, wherein the common layer comprises a second main portion and a second connecting portion, the second main portion is located between the first metal layer and the first main portion, the second connecting portion is located in the undercut opening, at least part of the second connecting portion is disconnected from the first main portion at the inner wall of the undercut opening, and the second connecting portion is located between the first connecting portion and the substrate.
